(19) United States
(12) Patent Application Publication
(10) Pub. No.: US 2024/0266291 A1
(43) Pub. Date: Aug. 8, 2024

(54) MATERIAL FOR METAL LINE, METAL LINE IN SEMICONDUCTOR DEVICE AND METHOD FOR FORMING METAL LINE IN SEMICONDUCTOR DEVICE

(71) Applicant: Samsung Electronics Co., Ltd., Suwon-si (KR)

(72) Inventors: Eunyoung LEE, Suwon-si (KR); Wei GUO, Huizhou City (CN); Wulin HE, Huizhou City (CN); Buseo CHOI, Suwon-si (KR); Sanghyun PARK, Suwon-si (KR); Wonwoong CHUNG, Suwon-si (KR)

(73) Assignees: Samsung Electronics Co., Ltd., Suwon-si (KR); HUIZHOU TOP METAL MATERIAL CO., LTD., Huizhou City (CN)

(21) Appl. No.: 18/479,211

(22) Filed: Oct. 2, 2023

(30) Foreign Application Priority Data
Feb. 2, 2023 (KR) 10-2023-0014308

(51) Int. Cl. H01L 23/532; H01L 21/3205; H01L 21/3213; H01L 21/768; H01L 23/528

(52) U.S. Cl. CPC H01L 23/53219; H01L 21/32051; H01L 21/32136; H01L 21/32139; H01L 21/76834; H01L 23/528; H01L 23/53223; H01L 23/5329

(57) ABSTRACT

A material including an alloy including aluminum of 99% by weight to 99.8% by weight, copper of 0.1% by weight to 0.5% by weight, and scandium of 0.1% by weight to 0.5% by weight, a metal line in a semiconductor device including the material, and a method for forming the metal line in the semiconductor device may be provided.

### CROSS-REFERENCE TO RELATED APPLICATION

This application claims priority to and the benefit of Korean Patent Application No. 10-2023-0014308 filed in the Korean Intellectual Property Office on Feb. 2, 2023, the entire contents of which are incorporated herein by reference.

### BACKGROUND

### (a) Field of the Invention

The present disclosure relates to materials for a metal line, metal lines in semiconductor devices, and methods for forming metal lines in semiconductor devices.

### (b) Description of the Related Art

As the size of a semiconductor chip is smaller, reliability deterioration due to electro-migration (EM) and stress-migration (SM) caused by the design rule shrinkage of a back end of line (BEOL) metal line has been a problem. In the case of DRAM, an Al line is formed and then annealing is performed to passivate Si dangling bonds that form the trap in a channel of a transistor in order to improve the transistor characteristics. At this time, as a passivation material remains on the Al line, which intensified deterioration of SM reliability. The deterioration of SM reliability of the Al line occurs by the Al atom or void diffusion through an Al grain boundary due to the residual stress caused by a difference between Al with a large coefficient of thermal expansion and surrounding materials with relatively small coefficients of thermal expansion. Accordingly, research and development on an Al alloy doped with a material, which is capable of strengthening stress resistivity and reducing or preventing the Al diffusion during segregation on the Al grain boundary in order to improve SM reliability, have been conducted.

### SUMMARY

One aspect of the present disclosure provides a metal line in a semiconductor device that is capable of solving a problem of reliability deterioration occurring by the Al atom or void diffusion through an Al grain boundary due to residual stress caused by differences in the coefficient of thermal expansion between Al with a large coefficient of thermal expansion and surrounding materials with relatively small coefficients of thermal expansion.

According to an example embodiment, a material for a metal line in a semiconductor device includes aluminum of 99% by weight to 99.8% by weight, copper of 0.1% by weight to 0.5% by weight, and scandium of 0.1% by weight to 0.5% by weight.

A content of the copper may be greater than a content of the scandium.

The alloy may include aluminum of 99.25% by weight to 99.64% by weight, copper of 0.26% by weight to 0.5% by weight, and scandium of 0.1% by weight to 0.25% by weight.

With respect to the copper of 100 parts by weight, a content of the scandium may be 50 parts by weight to 70 parts by weight.

The alloy may be Al_{99.5}Cu_{0.3}SC_{0.2}.

The material for the metal line in the semiconductor device may have a change rate of a grain size of 5% or less before and after heat treatment of 200° C. to 500° C. by Equation 1 below:

$$change rate ( \% ) of grain size before and after heat treatment = {[ \vert ( grain size after heat treatment - grain size before the heat treatment ) \vert / grain size before the heat treatment ]}^{*} 100 \qquad [ Equation1 ]$$

The grain size may be measured through an SEM image under a condition of a magnification of 100 k.

In Equation 1 above, the grain size before the heat treatment may be 0.065 μm to 0.080 μm.

According to an example embodiment, a metal line in a semiconductor device includes an oxide layer and a lower metal layer buried in the oxide layer, a barrier layer on a part of a surface of the oxide layer, which includes the lower metal layer, an alloy on the barrier layer, a reflectance reducing layer on the alloy, and a passivation layer surrounding the barrier layer, the alloy, and the reflectance reducing layer, wherein the alloy may include aluminum of 99% by weight to 99.8% by weight, copper of 0.1% by weight to 0.5% by weight, and scandium of 0.1% by weight to 0.5% by weight.

The alloy may be the same as described above with respect to the material for the metal line in the semiconductor device.

The oxide layer may include silica.

The lower metal layer may include scandium.

The barrier layer may include TiAl, TiN, TiSiN, WN, TaN, Ta, Ti, Ru or a combination thereof.

The reflectance reducing layer may include TIN, Al or a combination thereof.

The passivation layer may include silica, silicon nitride or a combination thereof.

The alloy may be on the entire surface of the barrier layer, and then etched together with the barrier layer and the reflectance reducing layer, so that the barrier layer is on a part of a surface of the oxide layer, which includes the lower metal layer, and the passivation layer may be on the oxide layer where the barrier layer is not present and may surround the etched barrier layer, the etched alloy, and the etched reflectance reducing layer.

According to an example embodiment, a method for forming a metal line in a semiconductor device includes forming an oxide layer and a lower metal layer buried in the oxide layer on a semiconductor substrate, forming a barrier layer on an entire surface of the oxide layer, which includes the lower metal layer, forming an alloy on the barrier layer, forming a reflectance reducing layer on the alloy, patterning the alloy, along with the reflectance reducing layer, to form the metal line by performing a photo and etching process, passivating the metal line, the patterned reflectance reducing layer, and the barrier layer, with an insulator, and performing a heat treatment, wherein the alloy may include an alloy including aluminum of 99% by weight to 99.8% by weight, copper of 0.1% by weight to 0.5% by weight, and scandium of 0.1% by weight to 0.5% by weight.

The alloy may be the same as described above with respect to the material for the metal line in the semiconductor device.

The insulator may include silica, silicon nitride or a combination thereof.

The heat treatment may be performed at a temperature of 200° C. to 500° C. by flowing gas including H₂, N₂, D₂, Ar, or a combination thereof.

The alloy may be deposited to a thickness of 400 nm to 700 nm at a temperature of 400° C. to 450° C. using a physical vapor deposition (PVD) method.

The purity of the alloy deposited using the PVD method may be 99.999% or more.

According to the material of the metal line in the semiconductor device according to some example embodiments, stress due to the grain growth may be reduced by suppressing the grain growth after heat treatment, the atom diffusion may be reduced or hindered in the alloy, and thus, resistivity to electro-migration (EM) and stress-migration (SM), which are desired for the PVD process, may be significantly improved. Therefore, according to the method for forming the metal line including the material of the metal line, reliability issues of the semiconductor device due to the deterioration of electro-migration (EM) and stress-migration (SM) may be reduced or prevented.

### BRIEF DESCRIPTION OF THE DRAWINGS

FIG. 1 is a diagram showing copper (Cu) blocking the void or atom diffusion on the grain boundary of an alloy according to Comparative Example 1.

FIG. 2 is a diagram showing copper (Cu) and scandium (Sc) blocking the void or atom diffusion on the grain boundary of an alloy according to an example embodiment.

FIG. 3 is a graph showing coefficients of thermal expansion according to the melting point of various metals.

FIG. 4 is a graph showing the electronegativity according to the atomic radius of various metals.

FIG. 5 is a diagram illustrating a method for forming a metal line in a semiconductor device according to an example embodiment.

### DETAILED DESCRIPTION

Hereinafter, the present disclosure will be described in more detail with reference to the accompanying drawings, in which some example embodiments of the present disclosure are shown. As those skilled in the art would realize, the described example embodiments may be modified in various different ways, without departing from the spirit or scope of the present disclosure. In the drawings, parts that are not related to the description may be omitted. Like or similar reference numerals designate like elements throughout the specification. In addition, the accompanying drawings are only for easy understanding of the example embodiments disclosed in the present specification, do not limit the technical concepts disclosed in the present specification, and should be understood to include all changes, equivalents or substitutes included in the spirit and technical scope of the present inventive concepts.

In addition, because the size and thickness of each element shown in the drawings are arbitrarily shown for convenience of description, the present inventive concepts are not necessarily limited to those shown. In the drawings, the thicknesses of layers, films, panels, regions, etc., are exaggerated for clarity. In addition, in the drawings, for convenience of description, the thicknesses of some layers and regions are exaggerated.

In addition, it will be understood that when an element such as a layer, film, region, or substrate is referred to as being “on” another element, it may be directly on the other element or intervening elements may also be present. In contrast, when an element is referred to as being “directly on” another element, there are no intervening elements present. In addition, being “above” or “on” a reference element means being located above or below the reference element, and does not necessarily mean being located “above” or “on” in the opposite direction of gravity.

Also, it will be understood that, when an element is referred to as being “connected” or “coupled” to another element, the element may be directly connected or coupled to the other element, both elements may face each other, or intervening elements may be present. In contrast, when an element is referred to as being “directly connected” or “directly coupled” to another element, there are no intervening elements present.

In addition, it should be understood that terms such as “comprise” or “have” are intended to designate that a feature, number, step, operation, element, parts, or combinations thereof described in the specification exists, but do not preclude the presence or addition of one or more other features or numbers, steps, operations, elements, parts, or combinations thereof. Therefore, when a portion “includes” an element, it means that other elements are not excluded but may be further included unless otherwise stated.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Aluminum has been mainly used as a material for a metal line in a semiconductor device according to the related art. The atomic number of aluminum is 13, which is relatively small, and thus has a problem in that electro migration occurs when the number of electrons is large, or the speed is high due to the momentum transfer occurring even by an electron flux. The electro migration (EM) is a phenomenon that metal atoms diffuse by the flow of electrons, and thus the performance of a device is reduced because metal atoms do not exist at positions where they are supposed to be and voids (holes) are formed due to the escape of the metal atoms, and the escaped metal atoms are piled up to form a hillock and/or form bridges connected to other circuits.

That is, rapid migration occurs in Al through a grain boundary. For example, Al atoms may diffuse by the electron flow to form void(s) on the left side and may pile up to form hillock(s) on the right side.

Therefore, in order to solve the electro migration (EM) phenomenon, an alloy in which aluminum is used as a main material and copper or silicon is added thereto is widely used as a material for a metal line currently.

However, the alloy in which copper or silicon is added to aluminum may not block or prevent stress-migration, that is, a phenomenon occurred by the void diffusion due to a stress gradient as in the aluminum metal line. Therefore, in the semiconductor device according to the related art, when forming a metal line or performing various heat treatments in a subsequent process, the alloy, which is the material for the metal line, may be functionally affected and reliability may be more seriously damaged due to deterioration caused by stress-migration. For example, in the case of DRAM, a failure phenomenon such as a metal line connection may increase.

A material for a metal line in a semiconductor device according to an example embodiment includes an alloy including aluminum as a main material and copper and scandium. At this time, by limiting the content ratios of the three elements of aluminum, copper, and scandium to aluminum of 99% by weight to 99.8% by weight, copper of 0.1% by weight to 0.5% by weight, and scandium of 0.1% by weight to 0.5% by weight, the problem of reliability caused by the deterioration of electro-migration (EM) and stress-migration (SM) (e.g., a metal line disconnection) may be improved, thereby improving durability of the metal line in the semiconductor device.

As described above, the deterioration of SM reliability of an aluminum line may occur by aluminum atom or void diffusion through an Al grain boundary due to the residual stress caused by a difference between aluminum with a large coefficient of thermal expansion and surrounding materials with relatively small coefficients of thermal expansion (e.g., may be attributed to stress caused by a difference in coefficient of thermal expansion (CTE)). Thus, it is important to introduce a material with a small difference in the CTE than silica, which is a lower layer of an alloy including aluminum, to the existing alloy of aluminum and copper.

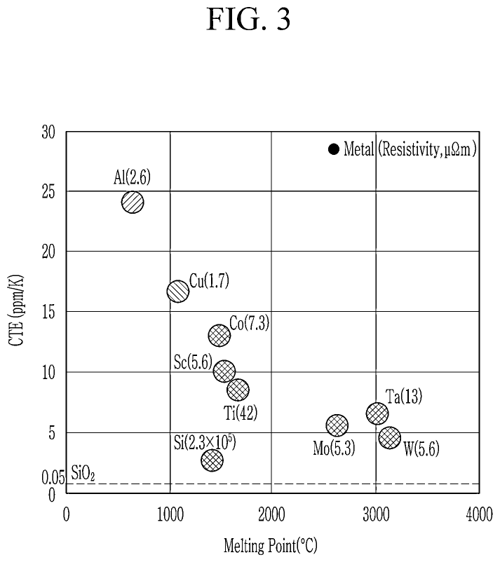

Referring to FIG. 3, scandium (Sc) has a CTE of 5.6 ppm/K. Scandium (Sc) shows a small difference in the CTE with silica (SiO₂) compared to copper (Cu), which has the CTE of about 17 ppm/K.

On the other hand, the higher the melting point of a metal element, the lower the speed at which a void is generated. Thus, it is advantageous to select a metal element with a high melting point from the viewpoint of void resistivity. FIG. 3, it may be seen that scandium (Sc) has a higher melting point than copper (Cu).

Furthermore, in an existing alloy (e.g., an alloy in which copper is added to aluminum), copper exists on the Al grain boundary and blocks or prevents the void or atom diffusion, thereby suppressing electro migration and stress-migration to some extent but has not shown excellent performance in terms of the ability to suppress stress migration. Research has been conducted to figure out the causes of insufficient suppression of the stress migration, and it has been discovered that such phenomenon is due to the fact that copper has a high solid-solubility with Al, and its crystal structure is a face-centered cubic structure, which is the same as that of aluminum.

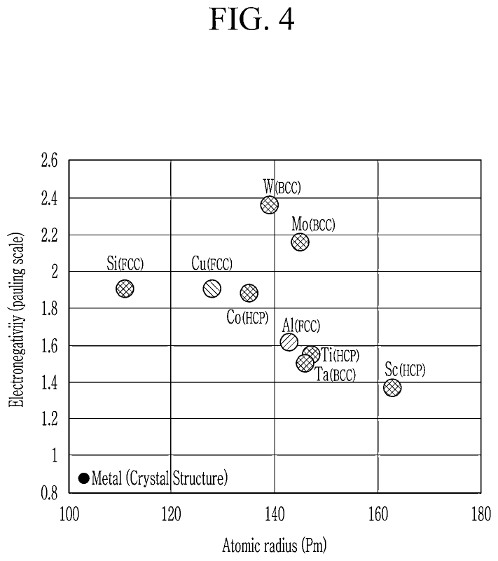

Therefore, it is advantageous to use a metal element having a low solid-solubility with respect to the aluminum. The lower the solid-solubility of the metal element with respect to aluminum, the higher the possibility of the metal element to exist on the grain boundary. Thus, it may be easily used as a material playing a blocking role on the grain boundary, which is a diffusion path, through which atoms diffuse. It may be seen that the greater the difference of a radius of a metal element from a radius of the aluminum atom or the greater the difference of an electronegativity of the metal element from an electronegativity of the aluminum atom, and the metal element whose crystal structure is not a face-centered cubic structure is suitable. Referring to FIG. 4, scandium (Sc) is suitable because it has a radius greater than the radius of the aluminum atom and an electronegativity of about 1.4, which is different from the electronegativity (about 1.6) of the aluminum atom, and furthermore, its crystal structure is a hexagonal close packed structure, which is different from the crystal structure of aluminum.

That is, when the element X has a hexagonal close packed (HCP) or body-centered cubic (BCC) structure rather than a face-centered cubic (FCC) structure, its solid-solubility with respect to aluminum decreases.

For example, the alloy may include aluminum, copper and scandium. For example, the alloy may be an Al—Cu—Sc alloy. When the alloy includes aluminum, copper, and scandium, atom diffusion may be effectively and significantly suppressed. When another elements, such as titanium, are added thereto, the relative content of scandium may be affected, and thus the atom diffusion is not effectively suppressed, thereby reducing the stress migration suppression ability.

For example, the aluminum may be included in an amount of 99.0% by weight to 99.8% by weight with respect to the total amount of the alloy.

For example, the copper and scandium may be included in an amount of 0.1% by weight to 0.5% by weight, respectively, with respect to the total amount of the alloy. When the amount of scandium is excessively reduced to less than 0.1% by weight with respect to the total amount of the alloy, it is difficult to sufficiently implement the stress migration suppression ability by scandium. In addition, when the scandium is excessively increased to more than 0.5% by weight with respect to the total amount of the alloy, a technical problem that a line resistivity due to impurity scattering increases above a reference value may occur.

For example, the material for the metal line in the semiconductor device according to an aspect may be expressed in Chemical Formula 1 below.

AlₓCu_{y}SC_{z} [Chemical Formula 1]

(In Chemical Formula 1, x, y, and z each mean the mixing weight ratio of each element, wherein x is 99% by weight to 99.8% by weight, y is 0.1% by weight to 0.5% by weight, and z is 0.1% by weight to 0.5% by weight.)

The material for the metal line in the semiconductor device according to an aspect is an alloy, in which scandium (Sc) is present on the aluminum (Al) grain boundary compared to the Al—Cu alloy, thereby having the effect of better blocking the atom or void diffusion than when only copper (Cu) is present. The alloy which is the material for the metal line in the semiconductor device according to an aspect has less grain growth occurring after heat treatment, and thus, the atom diffusion is reduced, and stress migration is better suppressed, thereby achieving improvement of reliability.

Specifically, the material for the metal line in the semiconductor device may have a change rate of grain size of 5% or less, 4% or less, 3% or less, 2% or less, 0.1% or more, 0.1% to 5%, 0.1% to 4%, 0.1% to 3%, or 0.1% to 2% before and after heat treatment of 200° C. to 500° C. by Equation 1 below.

$$change rate ( \% ) of grain size before and after heat treatment = {[ \vert ( grain size after heat treatment - grain size before heat treatment ) \vert / grain size before heat treatment ]}^{*} 100. \qquad [ Equation1 ]$$

In the material for the metal line in the semiconductor device, when the change rate of grain size before and after heat treatment of 200° C. to 500° C. according to Equation 1 is excessively increased to more than 5%, stress migration increases, and it is difficult to secure reliability.

The grain size may be measured through an SEM image under the condition of a magnification of 100 k. For example, the grain size may be measured through the SEM image using a method of obtaining an average value of the grain size formed on an arbitrary straight line with a length of 30 μm.

In Equation 1 above, |(grain size after heat treatment−grain size before heat treatment)|means an absolute value of (grain size after heat treatment−grain size before heat treatment).

In Equation 1 above, the grain size before heat treatment may be 0.065 μm to 0.080 μm. In Equation 1 above, when the grain size before an annealing process is excessively reduced to less than 0.065 μm, etc., an excessive grain recrystallization may occur during a subsequent annealing process and the resulting stress may deteriorate stress migration phenomenon.

For example, an excessive content of the copper included in the material for the metal line in the semiconductor device according to an aspect may be contained compared to scandium. For example, with respect to the copper of 100 parts by weight, the content of scandium may be 50 parts by weight to 70 parts by weight. In this case, the atom diffusion may be reduced while suppressing the grain growth after heat treatment, and thus reliability due to suppression of stress migration may be improved. Because copper serves to suppress an electro migration failure, more than the above-mentioned certain content of copper is desired. Thus, when the copper is contained in a smaller content than scandium, a technical problem such as the electro migration failure may occur.

For example, the alloy may include aluminum of 99.25% by weight to 99.64% by weight, copper of 0.26% by weight to 0.5% by weight, and scandium of 0.1% by weight to 0.25% by weight. When the content of scandium is excessively reduced to less than 0.1% by weight with respect to the total content of the alloy, it is difficult to sufficiently implement a stress migration suppression ability by scandium. In addition, when the scandium is excessively increased to more than 0.25% by weight with respect to the total content of the alloy, a technical problem in which a line resistivity due to impurity scattering increases above a reference value may occur.

In addition, when the copper is excessively reduced to less than 0.26% by weight with respect to the total content of the alloy, the reliability failure due to stress migration and electro migration may occur. In addition, when the copper is excessively increased to more than 0.5% by weight with respect to the total content of the alloy, the technical problem in which the line resistivity due to impurity scattering increases above the reference value may occur.

A specific example of the alloy may be Al_{99.5}Cu_{0.3}Sc_{0.2}.

A metal line in a semiconductor device according to another aspect includes an alloy that is a material for the metal line in the semiconductor device.

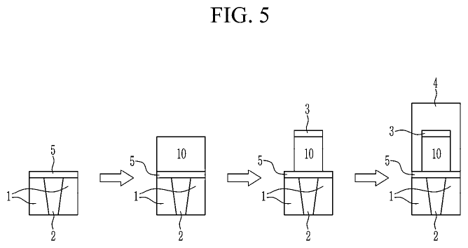

For example, referring to FIG. 5, the metal line in the semiconductor device includes an oxide layer 1 and a lower metal layer 2 buried in the oxide layer; a barrier layer 5 located on a part of the entire surface of the oxide layer including the lower metal layer; an alloy 10 located on the barrier layer; a reflectance reducing layer 3 located on the alloy; and a passivation layer 4 surrounding the barrier layer, the alloy, and the reflectance reducing layer. The alloy may be the above-described alloy.

For example, the alloy may include an alloy including aluminum of 99% by weight to 99.8% by weight, copper of 0.1% by weight to 0.5% by weight, and scandium of 0.1% by weight to 0.5% by weight, as described above.

For example, the oxide layer may include silica. When the oxide layer includes silica, relatively desirable effect may be implemented when applying scandium (Sc) which has the smallest difference in the CTE from silica. The oxide layer may function as an insulator to prevent electrical connection between adjacent metal lines. Considering this functional aspect, it may be advantageous for the oxide layer to contain silica. The oxide layer may be deposited on a semiconductor substrate (not shown), and a metal (e.g., a scandium layer) may be buried in the oxide layer as described below.

For example, the lower metal layer may include scandium. The lower metal layer may function as a contact layer connecting a lower metal line and an alloy (the material for the metal line) located thereon and transferring power and signal.

For example, the barrier layer may include TiAl, TiN, TiSiN, WN, TaN, Ta, Ti, Ru or a combination thereof. The barrier layer may be a single layer or a plurality of layers. The barrier layer may mitigate or prevent in advance a phenomenon in which an alloy formed by an alloy forming process described below diffuses into a lower oxide layer and the lower metal layer and generates a void in the alloy.

For example, the reflectance reducing layer may include TIN, Al or a combination thereof. The reflectance reducing layer has the composition as described above, which may reduce a high reflectance of aluminum of an alloy, which contains aluminum as a main material and located below the reflectance reducing layer, thereby improving the efficiency of a photo process during a metal line forming process described below.

For example, the passivation layer may include silica, silicon nitride or a combination thereof. The passivation layer has the composition as described above, which may reduce or prevent damage to the alloy containing aluminum as the main material during the metal line forming process described below.

For example, the alloy may be located on the entire surface of the barrier layer, and then etched together with the barrier layer and the reflectance reducing layer, so that the barrier layer is located on a part of the entire surface of the oxide layer including the lower metal layer, and the passivation layer may be located on the oxide layer where the barrier layer is not located and may surround the etched barrier layer, the etched alloy, and the etched reflectance reducing layer. That is, the alloy may be deposited on the entire surface of the barrier layer deposited on the entire surface of the oxide layer, and then the reflectance reducing layer may be deposited on the entire surface of the alloy, and then the barrier layer, the alloy, and the reflectance reducing layer may be etched together through a photo and etching process, so that the barrier layer may be located on only a part of the entire surface of the oxide layer, and then the passivation layer may passivate the etched barrier layer, the etched alloy, and the etched reflectance reducing layer.

According to another aspect, a method for forming the metal line in the semiconductor device includes forming an oxide layer and a lower metal layer buried in the oxide layer on a semiconductor substrate; forming a barrier layer on the entire surface of the oxide layer including the lower metal layer; forming an alloy on the barrier layer; forming a reflectance reducing layer on the alloy; patterning the metal line on the alloy by performing a photo and etching process; passivating the alloy on which the metal line is patterned, the barrier layer, and the reflectance reducing layer with an insulator; and performing heat treatment.

For example, the alloy may include an alloy including aluminum of 99% by weight to 99.8% by weight, copper of 0.1% by weight to 0.5% by weight, and scandium of 0.1% by weight to 0.5% by weight, as described above.

Hereinafter, the method for forming the metal line in the semiconductor device is described with reference to FIG. 5.

As shown in FIG. 5, in the method for forming the metal line in the semiconductor device according to an aspect, silica is first deposited as the oxide layer 1 on a semiconductor substrate (not shown), and a metal (e.g., the scandium layer 2) is buried in the oxide layer 1.

Thereafter, the barrier layer 5 is deposited to a thickness of about 500 Å or less on the entire surface of the oxide layer 1 including the scandium layer 2. At this time, the barrier layer 5 may be deposited using plasma enhanced chemical vapor deposition (PECVD), but the deposition method is not necessarily limited thereto. After depositing the barrier layer 5, a CMP process, etc. may be performed to further reduce the thickness of the barrier layer 5.

Thereafter, an alloy or an alloy layer 10 having a thickness of about 4,000 Å to about 5,000 Å is formed by depositing an alloy, in which a main material is aluminum (which is the material for the metal line in the semiconductor device described above), on the barrier layer 5, and then a TiN film 3 is formed as the reflectance reducing layer 3 on the alloy or alloy layer 10 to a thickness of about 300 Å to about 700 Å. The alloy or alloy layer 10 may be deposited to a thickness of about 400 nm to about 700 nm at a high temperature of 380° C. to 450° C. using a physical vapor deposition (PVD) method, and the TIN film which is the reflectance reducing layer 3 may be deposited to a thickness of about 100 Å to about 1,000 Å. At this time, the purity of the alloy 10 deposited using the PVD method may be 99.999% or more.

Subsequently, a photoresist pattern is formed on the TIN film 3 and a photo process is performed. The photoresist pattern needs to have a sufficient thickness to serve as a mask during an etching process using plasma described below.

Thereafter, the alloy or alloy layer 10 is selectively removed together with the barrier layer 5 and the TiN film 3 by an etching process, for example, a dry etching process, using a plasma in which a mixed gas of Cl₂ and BCl₃ is activated.

As shown in FIG. 5, the alloy or alloy layer 10 is patterned by dry etching using the photoresist pattern as a mask to form the metal line. At this time, the metal line needs to have some degree of selectivity with respect to the photoresist by securing a photoresist margin in a previous process.

Subsequently, after the dry etching process, the photoresist pattern is removed, and then a cleaning process is performed. At this time, no residue is generated by the barrier layer 5, and above all, a phenomenon in which the alloy or alloy of the alloy layer 10 diffuses into the oxide layer 1 therebelow or the scandium layer 2 which is the lower metal layer may be mitigated or prevented.

Thereafter, the metal line may be capped with an insulator. In other words, the alloy or alloy layer 10 and the TiN film 3, which is the reflectance reducing layer, may be passivated with the insulator. At this time, the insulator may include silica, silicon nitride, or a combination thereof. The alloy or alloy layer 10 is passivated using the insulator, and thus, damage to the alloy or alloy layer 10 may be mitigated or prevented.

An annealing process is performed by flowing gas to the passivated alloy or alloy layer 10. At this time, the annealing process may be performed while flowing gas such as hydrogen gas (H₂), nitrogen gas (N₂), deuterium gas (D₂), argon gas (Ar), etc. at about 200° C. to about 500° C.

Hereinafter, specific example embodiments of the present inventive concepts are proposed. However, the example embodiments described below are only intended to specifically illustrate or explain some examples of the present inventive concepts, and the present inventive concepts should not be limited thereto.

### Whether to Suppress a Grain Growth Before and After an Annealing Process of an Al—Cu Alloy and an Al—Cu—Sc Alloy

An Al_{99.5}—Cu_{0.5} alloy including Al of 99.5% by weight and Cu of 0.5% by weight (Comparative Example 1), an Al_{99.5}—Sc_{0.5} alloy including Al of 99.5% by weight and Sc of 0.5% by weight (Comparative Example 2), and an Al_{99.5}—Cu_{0.3}—Sc_{0.2} alloy including Al of 99.5% by weight, Cu of 0.3% by weight, and Sc of 0.2% by weight (Embodiment 1) are heat treated at a temperature of 400° C. for 120 minutes, and a grain size before and after heat treatment is measured using a method of obtaining an average value of the grain size formed on a straight line with a length of 130 μm through a SEM image under the condition of a magnification of 100 k by using an electron backscattered diffraction (EBSD) analysis (Quantax EBSD Detector, Bruker Co.), and the results are shown in Table 1 below.

In addition, a change rate of the grain size before and after heat treatment is obtained by Equation 1 below.

$$Change rate ( \% ) of grain size before and after heat treatment = {[ \vert ( grain size after heat treatment - grain size before heat treatment ) \vert / grain size before heat treatment ]}^{*} 100 \qquad [ Equation1 ]$$

TABLE 1

| | | | | change rate (%) |
|---|---|---|---|---|
| | | before heat | after heat | before and after |
| classification | alloy | treatment | treatment | heat treatment |
| Embodiment1 | Al_{99.5}—Cu_{0.3}—Sc_{0.2} | 0.078 | 0.077 | 1.8 |
| Comparative | Al_{99.5}—Cu_{0.5} | 0.0842 | 0.1176 | 39.7 |
| Example1 | | | | |
| Comparative | Al_{99.5}—Sc_{0.5} | 0.078 | 0.0848 | 8.7 |
| Example2 | | | | |

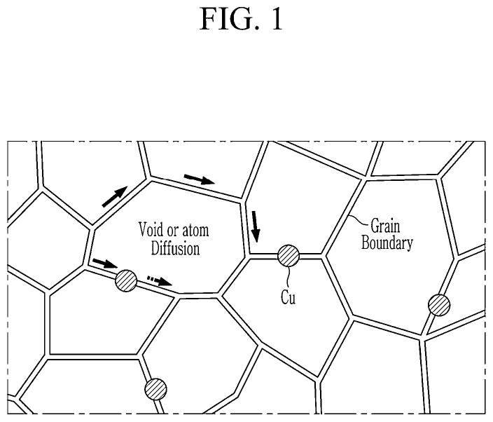

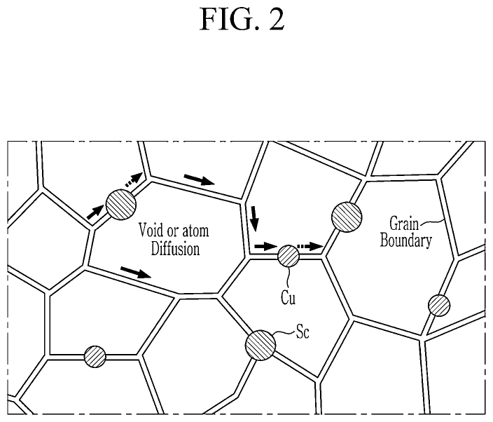

From Table 1, it may be confirmed that the grain growth of the alloy according to Embodiment 1 is suppressed after heat treatment compared to the alloys according to Comparative Example 1 and Comparative Example 2. It may be seen from this that the alloy according to Embodiment 1 effectively suppresses void or atom diffusion compared to the alloys according to Comparative Example 1 and Comparative Example 2 (see FIGS. 1 and 2).

Although some example embodiments of the present inventive concepts have been described above, the present inventive concepts are not limited thereto, and various modifications and implementations are possible within the scope of the claims and the description and the accompanying drawings, and it is natural that this also falls within the scope of the present inventive concepts.

What is claimed is:

1. A material for a metal line in a semiconductor device, comprising:
an alloy including,
aluminum of 99% by weight to 99.8% by weight,
copper of 0.1% by weight to 0.5% by weight, and
scandium of 0.1% by weight to 0.5% by weight.

2. The material of claim 1, wherein:
a content of the copper is greater than a content of the scandium.

3. The material of claim 1, wherein:
the alloy includes
aluminum of 99.25% by weight to 99.64% by weight,
copper of 0.26% by weight to 0.5% by weight, and
scandium of 0.1% by weight to 0.25% by weight.

4. The material of claim 1, wherein:
with respect to the copper of 100 parts by weight, a content of the scandium is 50 parts by weight to 70 parts by weight.

5. The material of claim 1, wherein:
the alloy is Al_{99.5}Cu_{0.3}SC_{0.2}.

6. The material of claim 1, wherein:
the material for the metal line in the semiconductor device has a change rate of a grain size of 5% or less before and after heat treatment of 200° C. to 500° C. by Equation 1 below:
$$change rate ( \% ) of grain size before and after heat treatment = {[ \vert ( grain size after the heat treatment - grain size before the heat treatment ) \vert / grain size before the heat treatment ]}^{*} 100. \qquad [ Equation1 ]$$

7. The material of claim 6, wherein:
the grain size is measured through an SEM image under a condition of a magnification of 100 k.

8. The material of claim 6, wherein:
In the Equation 1, the grain size before the heat treatment is 0.065 μm to 0.080 μm.

9. A metal line in a semiconductor device, comprising:
an oxide layer and a lower metal layer buried in the oxide layer;
a barrier layer on a part of a surface of the oxide layer, which includes the lower metal layer;
an alloy on the barrier layer;
a reflectance reducing layer on the alloy; and
a passivation layer surrounding the barrier layer, the alloy, and the reflectance reducing layer,
wherein the alloy includes aluminum of 99% by weight to 99.8% by weight, copper of 0.1% by weight to 0.5% by weight, and scandium of 0.1% by weight to 0.5% by weight.

10. The metal line of claim 9, wherein:
the oxide layer includes silica.

11. The metal line of claim 9, wherein:
the lower metal layer includes scandium.

12. The metal line of claim 9, wherein:
the barrier layer includes TiAl, TiN, TiSiN, WN, TaN, Ta, Ti, Ru or any combination thereof.

13. The metal line of claim 9, wherein:
the reflectance reducing layer includes TIN, Al or any combination thereof.

14. The metal line of claim 9, wherein:
the passivation layer includes silica, silicon nitride or any combination thereof.

15. The metal line of claim 9, wherein:
the passivation layer is on the oxide layer where the barrier layer is absent and surrounds the barrier layer, the alloy, and the reflectance reducing layer.

16. A method for forming a metal line in a semiconductor device, comprising:
forming an oxide layer and a lower metal layer buried in the oxide layer on a semiconductor substrate;
forming a barrier layer on an entire surface of the oxide layer, which includes the lower metal layer;
forming an alloy on the barrier layer;
forming a reflectance reducing layer on the alloy;
patterning the alloy, along with the reflectance reducing layer, to form the metal line by performing a photo and etching process;
passivating the metal line, the patterned reflectance reducing layer, and the barrier layer with an insulator; and
performing a heat treatment,
wherein the alloy includes aluminum of 99% by weight to 99.8% by weight, copper of 0.1% by weight to 0.5% by weight, and scandium of 0.1% by weight to 0.5% by weight.

17. The method of claim 16, wherein:
the insulator includes silica, silicon nitride or any combination thereof.

18. The method of claim 16, wherein:
the heat treatment is performed at a temperature of 200° C. to 500° C. by flowing gas including H₂, N₂, D₂, Ar, or any combination thereof.

19. The method of claim 16, wherein:
the alloy is deposited to a thickness of 400 nm to 700 nm at a temperature of 400° C. to 450° C. using a physical vapor deposition (PVD) method.

20. The method of claim 19, wherein:
a purity of the alloy deposited using the PVD method is 99.999% or more.
